(19) United States
(12) Patent Application Publication
(10) Pub. No.: US 2022/0320023 A1
(43) Pub. Date: Oct. 6, 2022

(54) Ceramic Encapsulating Casing and Mounting Structure Thereof

(71) Applicant: THE 13TH RESEARCH INSTITUTE OF CHINA ELECTRONICS TECHNOLOGY GROUP CORPORATION, Shijiazhuang (CN)

(72) Inventors: Zhentao Yang, Shijiazhuang (CN); Linjie Liu, Shijiazhuang (CN); Yuan Fang, Shijiazhuang (CN)

(21) Appl. No.: 17/846,911

(22) Filed: Jun. 22, 2022

Related U.S. Application Data
(63) Continuation of application No. PCT/CN2020/123683, filed on Oct. 26, 2020.

(30) Foreign Application Priority Data
May 13, 2020 (CN) 202010402748.X

(51) Int. Cl. H01L 23/66; H01L 23/13; H01L 23/15; H01L 23/498

(52) U.S. Cl. CPC H01L 23/66; H01L 23/13; H01L 23/15; H01L 23/49822; H01L 23/49833; H01L 23/49838; H01L 23/49816; H01L 24/48

(57) ABSTRACT

A ceramic encapsulating casing and a mounting structure thereof are provided. The ceramic encapsulating casing includes a ceramic substrate, a ceramic insulator, a cover plate and a pad structure. The ceramic substrate is provided with a cavity with an upward opening. The ceramic insulator is disposed on the ceramic substrate and provided with a radio frequency transmission structure. The pad structure is arranged on a bottom surface of the ceramic substrate. and includes a plurality of second pads that are arranged for transmitting signals and arranged in an array manner. A plurality of solder balls are attached to the plurality of second pads in one-to-one correspondence.

### CROSS-REFERENCE TO RELATED APPLICATIONS

This application is a continuation application of International Application No. PCT/CN2020/123683, filed on Oct. 26, 2020, which claims priority to Chinese Patent Application No. CN 202010402748.X, filed on May 13, 2020. The disclosures of the aforementioned applications are hereby incorporated herein by reference in their entireties.

### TECHNICAL FIELD

The application belongs to the technical field of chip encapsulating, and particularly relates to a ceramic encapsulating casing and a mounting structure thereof.

### BACKGROUND

With the continuous development of microwave semiconductor technology, the operating frequency of elements (e.g., chips) is getting higher and higher which requires the encapsulating casing to adapt to higher frequency elements and smaller standing waves. The metal wall mounted ceramic insulator structure casing is an ideal encapsulate form suitable for encapsulating higher frequency elements. It can seal one or more microwave and millimeter-wave semiconductor chips in a separate box, and realize the interconnection of microwave signals with external circuits through ceramic insulators as input and output terminals. In this case, the entire casing is a fully sealed structure, which isolates the elements from the erosion of the external environment, and the elements has high reliability. In the overall structure of the casing, the ceramic insulator is embedded between the metal sealing frame and the base. One end of the ceramic insulator is connected with the external circuit through the outer lead, and the other end of the ceramic insulator extends into the encapsulating casing to connect with the semiconductor chip, thus the internal chip and the external circuit is connected.

Traditional microwave encapsulating casings like the metal wall mounted ceramic insulator casing mentioned above use a metal base as the chip carrier substrate. Although the heat dissipation performance of these casings is excellent, the structure of the insulator limits the number of its terminals, and high-density interconnection cannot be performed.

### SUMMARY

These and other problems are generally solved or circumvented, and technical advantages are generally achieved, by embodiments of the present application which provide a ceramic encapsulating casing and a mounting structure thereof.

### Technical Problems

The application provides a ceramic encapsulating casing and a mounting structure thereof and intends to solve the technical problem that the microwave encapsulating casing cannot perform high-density interconnection in the prior art.

### Technical Solutions

In order to achieve the above purpose, the technical solution adopted in the present application is to provide a ceramic encapsulating casing. This ceramic encapsulating casing includes a ceramic substrate, a ceramic insulator, a cover plate and a pad structure. The ceramic substrate is of being multi-layered structure and provided with a cavity with an upward opening. The ceramic insulator is disposed on the ceramic substrate and an upper portion of the ceramic substrate is provided with a radio frequency transmission structure. The radio frequency transmission structure penetrates a sidewall of the cavity and electrically connects to at least one chip or/and at least one passive component arranged in the cavity. The cover plate covers the cavity in a sealing manner. The pad structure is arranged on a bottom surface of the ceramic substrate. The pad structure includes a first pad and a plurality of second pads. The first pad is arranged for grounding and located under the ceramic insulator. The plurality of second pads are arranged for transmitting signals. The plurality of second pads are arranged in an array manner and surrounding the first pad. A plurality of solder balls are attached to the plurality of second pads in one-to-one correspondence. A welding contact surface that is stepped shaped is formed and includes a surface of the first pad and a plane that tangent to each solder ball at a bottom end of each solder ball.

The present application further provides a mounting structure of the ceramic encapsulating casing mentioned above. This mounting structure includes a circuit board. The circuit board is provided with a first stepped structure. An upper surface of the first stepped structure is flush with an upper surface of the ceramic insulator of the ceramic encapsulating casing. The upper surface of the first stepped structure is provided with a bonding structure for electrical connection with the radio frequency transmission structure. The circuit board is provided with a circuit board pad structure for welding with the pad structure.

### Advantageous Effects of the Disclosure

Compared with the prior art, the advantageous effects of the ceramic encapsulating casing provided by the present application are as follows: the ceramic encapsulating casing provided by the present application combines RF (Radio Frequency) transmission port technology and high hermetic multi-chip ceramic packaging technology which makes the ceramic encapsulating casing have excellent microwave performance, high-density wiring, high-integration component distribution and more terminals, thus effectively solving the problem that the traditional microwave encapsulating casings cannot perform high-density interconnection. The first pad and the second pads realize grounding and signal transmission respectively. The second pads adopt an array arrangement, this not only provides more terminals but also make the bonding fingers inside the ceramic encapsulating casing can be connected to the external circuit board through the nearest second pad. The conductive path is short, the wiring resistance is small, and the encapsulate parasitic parameters such as inductance are low, so excellent electrical properties is performed. Solder balls are connected to the second pads, and the lower ends of the solder balls are located on the same plane, which is suitable for surface mounting. Surface mount can effectively reduce the size of devices and improve the assembly density. In addition, the ceramic substrate of the ceramic encapsulating casing adopts a multi-layer structure, which can carry out multi-layer wiring, effectively improve the wiring density, and the ceramic insulator can make the casing suitable for encapsulating higher frequency chips. A variety of chips and/or a variety of passive components can be installed in the cavity of the ceramic substrate, which meets the user's encapsulating requirements for high integration.

Compared with the prior art, the advantageous effects of the mounting structure of the ceramic encapsulating casing provided by the present application are as follows: when installing, first weld the pad structure on the bottom of the ceramic substrate to the circuit board pad structure on the circuit board, and then use bonding wires to electrically connect the radio frequency transmission structure to the bonding structure on the first stepped structure. A first stepped structure is arranged on the circuit board, so there is basically no height difference between the bonding structure and the ceramic insulator, which facilitates bonding and connection and ensures impedance matching.

### BRIEF DESCRIPTION OF THE DRAWINGS

In order to more clearly illustrate the technical solutions in the embodiments of this application, the accompanying drawings to be used in the descriptions of the embodiments or the prior art will be briefly described below. Obviously, the accompanying drawings in the following description are only some embodiments of this application, and for a person of ordinary skill in the art, without involving any inventive effort, other accompanying drawings may also be obtained according to these accompanying drawings.

FIG. 1 is a sectional view of the ceramic encapsulating casing from the front view according to embodiments of this application;

FIG. 2 is a top view of the ceramic encapsulating casing according to embodiments of this application;

FIG. 3 is a bottom view of the ceramic encapsulating casing according to embodiments of this application;

FIG. 4 is a perspective view of the ceramic insulator of the ceramic encapsulating casing according to embodiments of this application;

FIG. 5 is a schematic assembly diagram of the ceramic encapsulating casing and the mounting structure according to embodiments of this application;

FIG. 6 is a schematic diagram of the shape of the welding contact surface between the ceramic encapsulating casing and the mounting structure according to embodiments of this application; and

FIG. 7 is a bottom view of the ceramic encapsulating casing without showing solder balls according to embodiments of this application.

### DETAILED DESCRIPTION OF ILLUSTRATIVE EMBODIMENTS

In order to make the technical problems to be solved by the present application, technical solutions and advantageous effects clearer, the present application will be further described in detail below with reference to the accompanying drawings and embodiments. It should be understood that the specific embodiments described herein are only used to explain the present application, but not to limit the present application.

In one embodiment, with reference to FIG. 1 to FIG. 5, the ceramic encapsulating casing provided by the present application includes a ceramic substrate 1, a ceramic insulator 2, a cover plate 3 and a pad structure 70. The ceramic substrate 1 is a multi-layered structure (the multi-layered structure is a known structure and not shown in the Figures.). The ceramic substrate 1 is provided with a cavity 5 with an upward opening. The ceramic insulator 2 is disposed on the ceramic substrate 1. A radio frequency transmission structure 6 is formed on the upper part of the ceramic insulator 2. The radio frequency transmission structure 6 penetrates a sidewall of the cavity 5. The radio frequency transmission 6 structure electrically connects to at least one encapsulated element arranged in the cavity 5. The encapsulated element maybe a chip(s) 4 or a passive component(s). The encapsulated element also maybe a chip(s) 4 and a passive component(s). The cover plate 3 covers the cavity 5 in a sealing manner. The ceramic substrate 1 cooperates with the cover plate 3 to seal the cavity 5 and provide physical protection for the encapsulated elements. The ceramic substrate 1 provides mechanical support for the encapsulated elements. The pad structure 70 arranged on a bottom surface of the ceramic substrate 1.

Compared with the prior art, the advantageous effects of the ceramic encapsulating casing provided by the present embodiment are as follows: the ceramic encapsulating casing provided by the present embodiment combines RF (Radio Frequency) transmission port technology and high hermetic multi-chip ceramic packaging technology which makes the ceramic encapsulating casing have excellent microwave performance, high-density wiring, high-integration component distribution and more terminals, thus effectively solving the problem that the traditional microwave encapsulating casings cannot perform high-density interconnection. In addition, the ceramic substrate 1 adopts a multi-layer structure, which can carry out multi-layer wiring, effectively improve the wiring density, and the ceramic insulator 2 can make the casing suitable for encapsulating higher frequency chips. A variety of chips 4 and/or a variety of passive components can be installed in the cavity 5, which meets the user's encapsulating requirements for high integration.

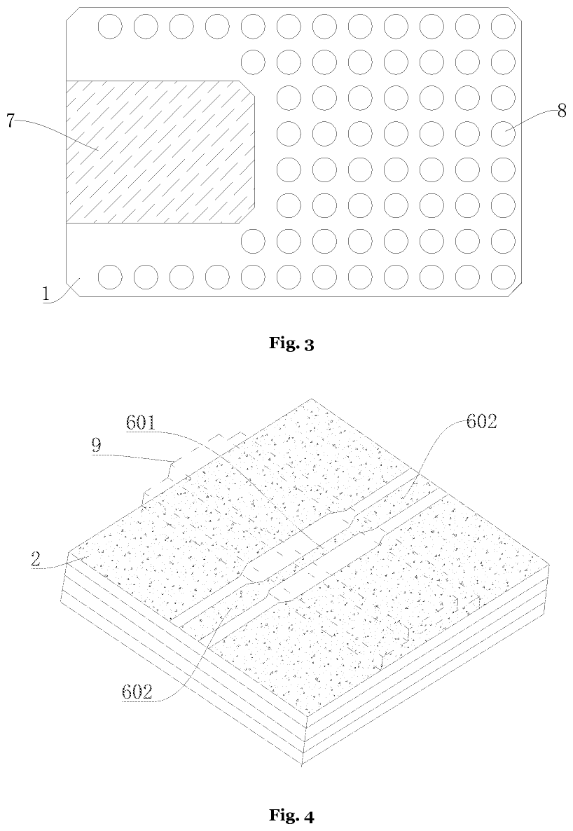

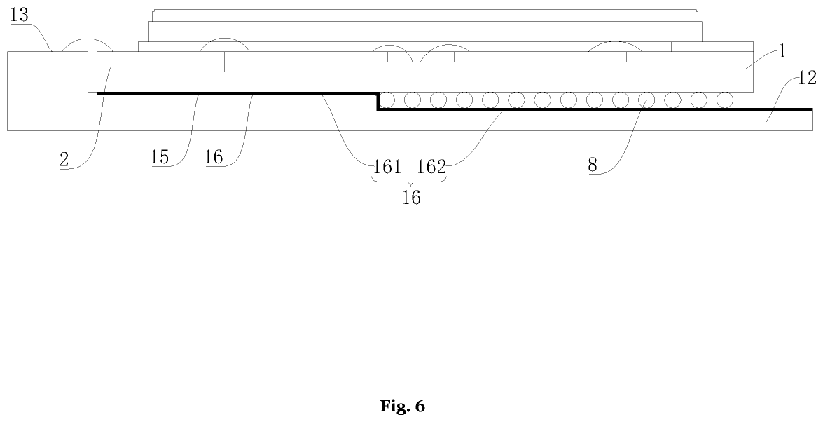

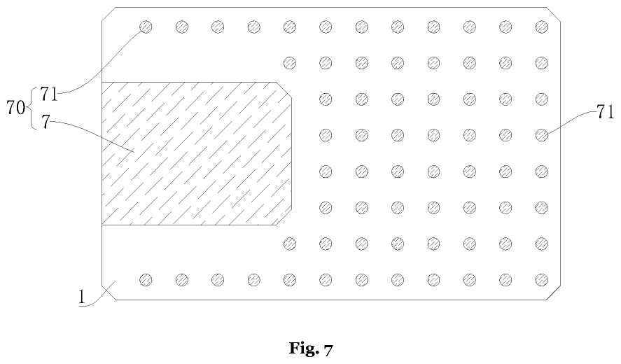

As shown in FIG. 7, the pad structure 70 includes a first pad 7 and a plurality of second pads 71. The first pad 7 and the second pads 71 are both formed on the bottom surface of the ceramic substrate 1. The first pad 7 as well as the second pads 71 may be a thin metal layer. The first pad 7 is arranged for grounding and located under the ceramic insulator 2. The second pads 71 are arranged for transmitting signals. The second pads 71 are arranged in an array manner and surrounding the first pad 7. A plurality of solder balls 8 are attached to the second pads 71 in one-to-one correspondence, such that each second pad 71 is arranged between a solder ball 8 and the bottom surface of the ceramic substrate 1. As shown in FIG. 3, each solder ball 8 is arranged on one second pad 71 and attaches to the corresponding second pad 71 in FIG. 3, and thus the second pads 71 are not shown. FIG. 7 is a bottom view of the ceramic encapsulating casing without showing the solder balls 8 in FIG. 3. As shown in FIG. 6, a welding contact surface 16 that is stepped shaped is formed between the ceramic encapsulating casing and the mounting structure. The welding contact surface 16 includes a surface 161 of the first pad 7 and a plane 162 that tangent to each solder ball 8 at a bottom end of each solder ball 8.

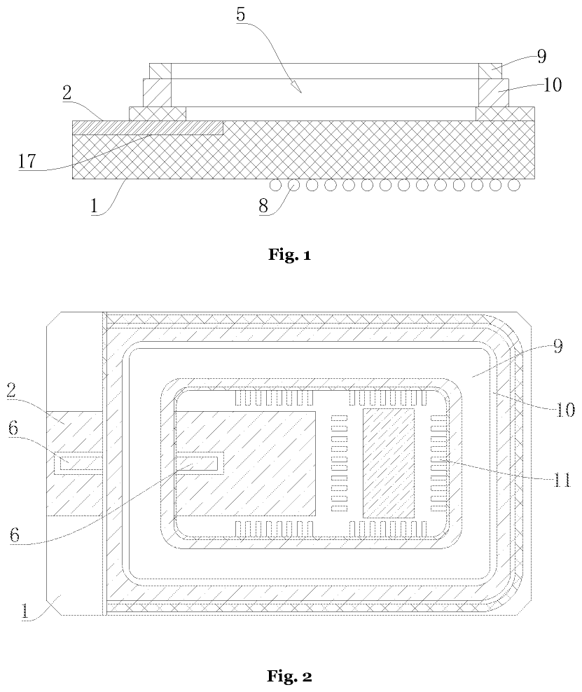

The first pad 7 and the second pads 71 realize grounding and signal transmission respectively. The area of the first pad 7 is large, and the grounding performance is good. As terminals of the ceramic encapsulating casing, the second pads 71 adopt an array arrangement, this not only provides more terminals but also make the bonding fingers 11 (shown in FIG. 2) inside the ceramic encapsulating casing can be connected to the pad of the external circuit board through the nearest second pad 71. The conductive path is short, the wiring resistance is small, and the encapsulate parasitic parameters such as inductance are low, so excellent electrical properties is performed. Solder balls 8 are connected to the second pads 71, and the lower ends of the solder balls 8 are located on the same plane 162, which is suitable for surface mounting. Surface mount can effectively reduce the size of devices and improve the assembly density.

The ceramic encapsulating casing provided by the present application is a ceramic casing that can meet the requirements of high frequency and high speed and can encapsulate multiple chips, and is suitable for military radar, electronic warfare receiver, satellite communication and other fields.

In one embodiment of this application, as shown in FIG. 1, the ceramic substrate 1 is provided with an embedded groove 17. The ceramic insulator 2 is embedded in the embedded groove 17 and fixed by welding. One end of the radio frequency transmission structure 6 on the ceramic insulator 2 is exposed outside the cavity 5, and is connected to an external circuit through the bonding wires 14. The other end of the radio frequency transmission structure 6 is located in the cavity 5, and is connected to the encapsulated elements such as chips 4 inside the cavity 5 through the bonding wires 14. The radio frequency transmission structure 6 plays the role of connecting the encapsulated elements and the external circuit.

In one embodiment of this application, the ceramic substrate 1 and the ceramic insulator 2 are integrally arranged, and they are made of the same material. The upper surface of the ceramic substrate 1 is substantially flush with the upper surface of the ceramic insulator 2. The integral arrangement makes the preparation of the ceramic encapsulating casing more convenient.

In one embodiment of this application, as shown in FIG. 4, the radio frequency transmission structure 6 comprises a stripline 601 and two coplanar waveguides 602. The stripline 601 runs through the sidewall of the cavity 5 and the two coplanar waveguides 602 are respectively arranged at two ends of the stripline 601. Two coplanar waveguides 602 are located inside and outside the cavity 5, respectively. The radio frequency transmission structure 6 adopts the form of stripline directly passing through the wall, forming a transmission structure of coplanar waveguide-stripline-coplanar waveguide. Meanwhile, the ceramic insulator 2 and the ceramic substrate 1 are integrally arranged, thus the overall microwave performance of the casing is good, the weight is light, and the integration degree is high. Optionally, ground holes for the grounding of the sealing area are arranged on both sides of the radio frequency transmission structure 6 inside the ceramic substrate 1.

The input and output ports of the radio frequency transmission structure 6 adopt a plane transmission structure, the transmission line is short, and the microwave signal is basically transmitted on the same plane. It effectively improves the external connection performance of the horizontal transmission of microwave signals through a wall. It can realize the matching transmission of microwave signals under the premise of ensuring the sealing requirements, with small transmission insertion loss, small size, easy integration, and is suitable for chip encapsulating with high operating frequency.

In one embodiment of this application, the ceramic substrate 1 is made of aluminum nitride (AlN) ceramic and made by multi-layer aluminum nitride ceramic tungsten metallization high temperature co-firing process.

AlN ceramic is an excellent ceramic encapsulating material for microwave and high-power applications. AlN ceramic has the advantages of high thermal conductivity, small dielectric constant, low dielectric loss and high mechanical strength. The thermal expansion coefficient of AlN ceramic is close to that of common chip materials (e.g., GaAs, Si), and large-sized and high-power chips can be directly encapsulated in AlN casing without adding a transition piece. This simplifies the encapsulating process and can effectively avoid failures due to thermal mismatch, thereby improving device reliability. In this embodiment, the ceramic substrate 1 is made by aluminum nitride multi-layer co-firing process which can carry out high-density multi-layer wiring, and can meet the requirements of high air tightness and high reliability.

In this embodiment, the preparation process of the ceramic encapsulating casing may be as follows: the raw material is casted→punched→hole metallized→printed→positioned→laminated→thermally cut into individual green ceramic pieces→sintered→nickel-plated→brazed→gold-plated, and finally individual integrated ceramic casings are formed and every ceramic casing has a pad array (i.e., the second pads).

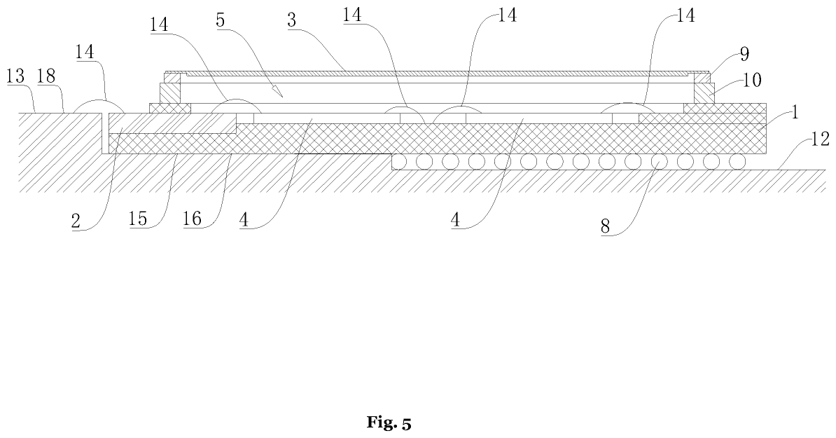

In one embodiment of this application, as shown in FIG. 1, FIG. 2 and FIG. 5, the ceramic encapsulating casing further includes a sealing ring 9 made of metal material. The sealing ring 9 surrounds the upward opening of the cavity 5. The cover plate 3 is covered on top of the sealing ring 9 thus sealing the cavity 5. The sealing ring 9 may be electrically connected to the first pad 7 using the ground holes mentioned above, and is grounded through the first pad 7.

Optionally, AgCu₂₈ solder is used for welding between the sealing ring 9 and the ceramic substrate 1. For the ceramic substrate 1 made of aluminum nitride, using high temperature solder AgCu₂₈ for welding can reserve sufficient temperature gradient for subsequent processing.

In one embodiment of this application, as shown in FIG. 1, FIG. 2 and FIG. 5, the ceramic encapsulating further includes a transition ring 10 between the sealing ring 9 and the ceramic substrate 1. The transition ring 10 is used to relieve a sealing stress between the sealing ring 9 and the ceramic substrate 1.

Aluminum nitride ceramic has a low coefficient of thermal expansion, but commonly used metal materials have high thermal expansion coefficients. Therefor welding of the ceramic substrate 1 made of Aluminum nitride ceramic and the sealing ring 9 made of metal is a mismatch welding which could lead to excessive residual stress inside the ceramic encapsulating casing and cracking on the side of the aluminum nitride ceramic, especially for aluminum nitride high-density encapsulate casings with larger cavity sizes. The transition ring 10 can achieve thermal expansion matching between the sealing ring 9 and the ceramic substrate 1, thus effectively reducing the residual stress. The transition ring 10 may be made of oxygen-free copper, tungsten-copper, molybdenum-copper, carboxy methylated cellulose/metal (metal oxide) composite material or Cu—MoCu—Cu composite material. By using the transition ring 10, the residual stress after brazing can be minimized while being compatible with parallel seam welding sealing, which will not cause the casing to crack and fail.

In one embodiment of this application, the sealing ring 9 is made of iron-cobalt-nickel alloy. A silver-copper solder is used for welding between the sealing ring 9 and the ceramic substrate 1.

The ceramic encapsulating casing provided by the present application adopts ceramic material and has pad array, and it has good microwave performance, high integration and does not need to use heat sink materials. Compared with the traditional casing, it has the advantages of small size, light weight, good heat dissipation performance and high integration. The design ideas provided by the present application can be widely used in the field of high-frequency and high-speed signal integrated encapsulating, and can prepare and process high-power and high-density AlN ceramic integrated casings.

Optionally, in the present application, the first pad may be rectangular and a minimum length and a minimum width of the first pad may be both 3 millimeters. Each second pad may be circular or rectangular. The number of the second pads may be at least 4. The ceramic encapsulating casing provided by the present application has high air tightness which can reach less than or equal to 1×10⁻¹ Pa·cm³/s, A4. The ceramic encapsulating casing high reliability and can meet temperature cycle: −65° C.˜175° C., 200 times, constant acceleration 30000 g, Y1 direction, 1 min.

The present application further provides a mounting structure of the ceramic encapsulating casing mentioned above. As shown in FIG. 5 and FIG. 6, the mounting structure includes a circuit board 12. The circuit board 12 is provided with a first stepped structure 13. An upper surface of the first stepped structure 13 is flush with an upper surface of the ceramic insulator 2 of the ceramic encapsulating casing. The upper surface of the first stepped structure 13 is provided with a bonding structure 18 for electrical connection with the radio frequency transmission structure 6. The circuit board 12 is provided with a circuit board pad structure for welding with the pad structure 70.

When installing, first weld the pad structure 70 on the bottom of the ceramic substrate 1 to the circuit board pad structure on the circuit board 12, and then use bonding wires to electrically connect the radio frequency transmission structure 6 to the bonding structure 18 on the first stepped structure 13. A first stepped structure 13 is arranged on the circuit board 12, so there is basically no height difference between the bonding structure 18 and the ceramic insulator 2, which facilitates bonding and connection and ensures impedance matching.

In one embodiment of this application, as shown in FIG. 5 and FIG. 6, the circuit board 12 is further provided with a second stepped structure 15. An upper surface of the second stepped structure 15 is provided with a third pad for welding with the first pad of the ceramic encapsulating casing. A lower surface of the second stepped structure 15 is provided with a fourth pad for welding with the second pads.

As shown in FIG. 6, after mounting is complete, the upper surface of the second stepped structure 15 fits together with the surface 161 of the first pad 7, and the lower surface of the second stepped structure 15 fits together with the plane 162 that tangent to each solder ball 8 at a bottom end of each solder ball 8. The surface 161 and the plane 162 form the welding contact surface 16.

The ceramic encapsulating casing provided by the present application is not provided with leads and realizes the electroplating of nickel-gold bonding fingers and pads in the following manner: connect all the signal lines to the sides of the ceramic substrate 1 inside the ceramic substrate 1, and then perform side printing on the sides of the ceramic substrate 1, so that all the electroplating lines are connected to the sides of the ceramic substrate 1. Finally, the four sides of the ceramic substrate 1 are clamped by a clamp to conduct conduction to realize electroplating.

In addition, in order to realize the isolation between the high-frequency radio frequency chip and the high-speed signal digital chip and improve the withstand voltage capability between the chips, after the chip bonding is completed, all chips in the entire casing cavity can be encapsulated with glue as a whole. Encapsulating the bonding wires of the chips with glue can effectively isolate different chips, prevent mutual discharge and breakdown between chips, and improve the voltage withstand capability of the entire device.

The above descriptions are only preferred embodiments of the present disclosure, and are not intended to limit the present disclosure. Any modifications, equivalent replacements and improvements made within the spirit and principle of the present disclosure shall be included within the protection scope of the present disclosure.

What is claimed is:

1. A ceramic encapsulating casing, comprising:
a ceramic substrate having a multi-layered structure and being provided with a cavity with an upward opening;
a ceramic insulator disposed on the ceramic substrate, wherein an upper portion of the ceramic substrate is provided with a radio frequency transmission structure that penetrates a sidewall of the cavity, and the radio frequency transmission structure electrically connects to at least one encapsulated element arranged in the cavity;
a cover plate for covering the cavity in a sealing manner; and
a pad structure arranged on a bottom surface of the ceramic substrate and comprising:
a first pad arranged for grounding and located under the ceramic insulator; and
a plurality of second pads configured for transmitting signals, wherein the plurality of second pads are arranged in an array manner and surround the first pad; and wherein:
a plurality of solder balls are attached to the plurality of second pads in one-to-one correspondence; and
a welding contact surface that is stepped shaped is formed, and the welding contact surface comprises a surface of the first pad and a plane that is in contact with each solder ball at a bottom end of each solder ball.

2. The ceramic encapsulating casing according to claim 1, wherein the ceramic substrate is provided with an embedded groove, and the ceramic insulator is embedded in the embedded groove.

3. The ceramic encapsulating casing according to claim 1, wherein the ceramic substrate and the ceramic insulator are integrally formed.

4. The ceramic encapsulating casing according to claim 3, wherein the ceramic insulator is made of a same material as the ceramic substrate.

5. The ceramic encapsulating casing according to claim 1, further comprising a sealing ring made of metal material, wherein the sealing ring surrounds the upward opening of the cavity, and the cover plate is arranged on top of the sealing ring thereby sealing the cavity.

6. The ceramic encapsulating casing according to claim 5, wherein a silver-copper solder is used for welding between the sealing ring and the ceramic substrate.

7. The ceramic encapsulating casing according to claim 5, wherein the sealing ring is made of iron-cobalt-nickel alloy.

8. The ceramic encapsulating casing according to claim 5, wherein the sealing ring is electrically connected to the first pad to realize grounding.

9. The ceramic encapsulating casing according to claim 5, further comprising a transition ring between the sealing ring and the ceramic substrate, wherein the transition ring is used to relieve a sealing stress between the sealing ring and the ceramic substrate.

10. The ceramic encapsulating casing according to claim 9, wherein a material for making the transition ring comprises oxygen-free copper, tungsten-copper, molybdenum-copper, carboxy methylated cellulose/metal (metal oxide) composite material, or Cu—MoCu—Cu composite material.

11. The ceramic encapsulating casing according to claim 1, wherein the ceramic substrate is made of aluminum nitride ceramic.

12. The ceramic encapsulating casing according to claim 11, wherein the ceramic substrate is made by a multi-layer aluminum nitride ceramic tungsten metallization high temperature co-firing process.

13. The ceramic encapsulating casing according to claim 1, wherein the radio frequency transmission structure comprises a stripline and two coplanar waveguides, wherein the stripline runs through the sidewall of the cavity, and the two coplanar waveguides are respectively arranged at two ends of the stripline.

14. The ceramic encapsulating casing according to claim 1, wherein the first pad is rectangular, and a minimum length and a minimum width of the first pad are three millimeters.

15. The ceramic encapsulating casing according to claim 1, wherein each second pad is circular or rectangular.

16. The ceramic encapsulating casing according to claim 1, wherein a number of the plurality of second pads is at least four.

17. A mounting structure of a ceramic encapsulating casing, wherein the ceramic encapsulating casing comprises:
a ceramic substrate having a multi-layered structure and being provided with a cavity with an upward opening;
a ceramic insulator disposed on the ceramic substrate, wherein an upper portion of the ceramic substrate is provided with a radio frequency transmission structure that penetrates a sidewall of the cavity, and the radio frequency transmission structure electrically connects to at least one encapsulated element arranged in the cavity;
a cover plate for covering the cavity in a sealing manner; and
a pad structure arranged on a bottom surface of the ceramic substrate and comprising:
a first pad arranged for grounding and located under the ceramic insulator; and
a plurality of second pads configured for transmitting signals, wherein the plurality of second pads are arranged in an array manner and surround the first pad; wherein:
a plurality of solder balls are attached to the plurality of second pads in one-to-one correspondence; and
a welding contact surface that is stepped shaped is formed, and the welding contact surface comprises a surface of the first pad and a plane that is in contact with to each solder ball at a bottom end of each solder ball; and
wherein the mounting structure comprises a circuit board, and wherein
the circuit board is provided with a first stepped structure;
an upper surface of the first stepped structure is flush with an upper surface of the ceramic insulator;
the upper surface of the first stepped structure is provided with a bonding structure for electrical connection with the radio frequency transmission structure; and
the circuit board is provided with a circuit board pad structure for welding with the pad structure.

18. The mounting structure according to claim 17, wherein the circuit board is further provided with a second stepped structure, and wherein
an upper surface of the second stepped structure is provided with a third pad for welding with the first pad; and
a lower surface of the second stepped structure is provided with a fourth pad for welding with the plurality of second pads.
